(19) United States
(12) Patent Application Publication
(10) Pub. No.: US 2019/0051853 A1
(43) Pub. Date: Feb. 14, 2019

(54) LIGHT-EMITTING ELEMENT AND DISPLAY DEVICE HAVING THE LIGHT-EMITTING ELEMENT

(71) Applicant: Japan Display Inc., Tokyo (JP)

(72) Inventor: Koji YASUKAWA, Tokyo (JP)

(21) Appl. No.: 16/021,688

(22) Filed: Jun. 28, 2018

(30) Foreign Application Priority Data
Aug. 9, 2017 (JP) 2017-153912

(51) Int. Cl. H01L 51/50; H01L 51/00; H01L 51/52

(52) U.S. Cl. CPC H01L 51/5072; H01L 51/5096; H01L 51/5203; H01L 51/5278; H01L 51/0085

(57) ABSTRACT

Disclosed is a light-emitting element including an anode, an emission layer over the anode, an electron-transporting layer over the emission layer, a first electron-injection layer over and in contact with the electron-transporting layer, a second electron-injection layer over and in contact with the first electron-injection layer, and a cathode over and in contact with the second electron-injection layer. The electron-transporting layer includes a first organic compound having an electron-transporting property higher than a hole-transporting property and further includes at least one of lithium, a lithium complex containing an 8-quinolinol ligand, and a magnesium complex containing an 8-quinolinol ligand. The first electron-injection layer includes at least one of lithium and a lithium complex containing an 8-quinolinol ligand. The second electron-injection layer includes a lanthanoid metal.

### CROSS REFERENCE TO RELATED APPLICATIONS

This application is based on and claims the benefit of priority from the prior Japanese Patent Application No. 2017-153912, filed on Aug. 9, 2017, the entire contents of which are incorporated herein by reference.

### FIELD

An embodiment of the present invention relates to a light-emitting element and a display device having the light-emitting element.

### BACKGROUND

An organic EL (Electroluminescence) display device is represented as an example of a display device. An organic EL display device possesses a plurality of organic light-emitting elements (hereinafter, referred to as light-emitting elements) formed over a substrate, and each light-emitting element has an electroluminescence layer (hereinafter, referred to as an EL layer) including an organic compound between a pair of electrodes (cathode and anode) as a fundamental structure. A potential difference provided between the pair of electrodes allows holes and electrons to be supplied to the EL layer. The holes and electrons are recombined in the EL layer, giving an excited state of an organic compound. A function as a display device is attained by utilizing the emission obtained when the excited state is radiatively deactivated to a ground state.

An EL layer is generally structured by a stack of a plurality of layers having a variety of functions (hereinafter, referred to as functional layers), and a hole-injection layer, a hole-transporting layer, an emission layer, an electron-transporting layer, an electron-injection layer, and the like are represented as the functional layers. When the holes and electrons are injected to the EL layer, an energy barrier is generated due to a difference between a work function of the electrode and a level of the highest occupied molecular orbital (HOMO) or the lowest unoccupied molecular orbital (LUMO) of the layer (hole-injection layer or electron-injection layer) in contact with the electrode. The EL layer is designed so as to reduce this energy barrier, thereby giving a display device with a reduced operation voltage and low power consumption. For example, Japanese Patent Application Publication No. 2007-36176 discloses a light-emitting element in which two electron-injection layers are disposed between a cathode and an emission layer in order to reduce an electron-injection barrier.

### SUMMARY

An embodiment of the present invention is a light-emitting element. The light-emitting element possesses an anode, an emission layer over the anode, an electron-transporting layer over the emission layer, a first electron-injection layer over and in contact with the electron-transporting layer, a second electron-injection layer over and in contact with the first electron-injection layer, and a cathode over and in contact with the second electron-injection layer. The electron-transporting layer includes a first organic compound having an electron-transporting property higher than a hole-transporting property and further includes at least one of lithium, a lithium complex containing an 8-quinolinol ligand, and a magnesium complex containing an 8-quinolinol ligand. The first electron-injection layer includes at least one of lithium and a lithium complex containing an 8-quinolinol ligand. The second electron-injection layer includes a lanthanoid metal.

An embodiment of the present invention is a display device including a pixel. The pixel possesses a light-emitting element including an anode, an emission layer over the anode, an electron-transporting layer over the emission layer, the electron-transporting layer, a first electron-injection layer over and in contact with the electron-transporting layer, a second electron-injection layer over and in contact with the first electron-injection layer, and a cathode over and in contact with the second electron-injection layer. The electron-transporting layer includes a first organic compound having an electron-transporting property higher than a hole-transporting property and further includes at least one of lithium, a lithium complex containing an 8-quinolinol ligand, and a magnesium complex containing an 8-quinolinol ligand. The first electron-injection layer includes at least one of lithium and a lithium complex containing an 8-quinolinol ligand. The second electron-injection layer includes a lanthanide metal.

### BRIEF DESCRIPTION OF DRAWINGS

FIG. 1 is a schematic cross-sectional view of a light-emitting element according to an embodiment of the present invention;

FIG. 2 is a schematic cross-sectional view of an emission layer of a light-emitting element according to an embodiment of the present invention;

FIG. 3 is a schematic cross-sectional view of a light-emitting element according to an embodiment of the present invention;

FIG. 4 is a schematic top view of a display device according to an embodiment of the present invention;

FIG. 5 is a schematic side view of a display device according to an embodiment of the present invention;

FIG. 6 is an example of an equivalent circuit of a pixel in a display device according to an embodiment of the present invention;

FIG. 7 is a schematic cross-sectional view of a light-emitting element according to an embodiment of the present invention; and

FIG. 8 is a schematic cross-sectional view of a light-emitting element according to an embodiment of the present invention.

### DESCRIPTION OF EMBODIMENTS

Hereinafter, the embodiments of the present invention are explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate.

In the present specification and claims, when a plurality of films is formed by processing one film, the plurality of films may have functions or rules different from each other. However, the plurality of films originates from a film formed as the same layer in the same process and has the same layer structure and the same material. Therefore, the plurality of films is defined as films existing in the same layer.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

### First Embodiment

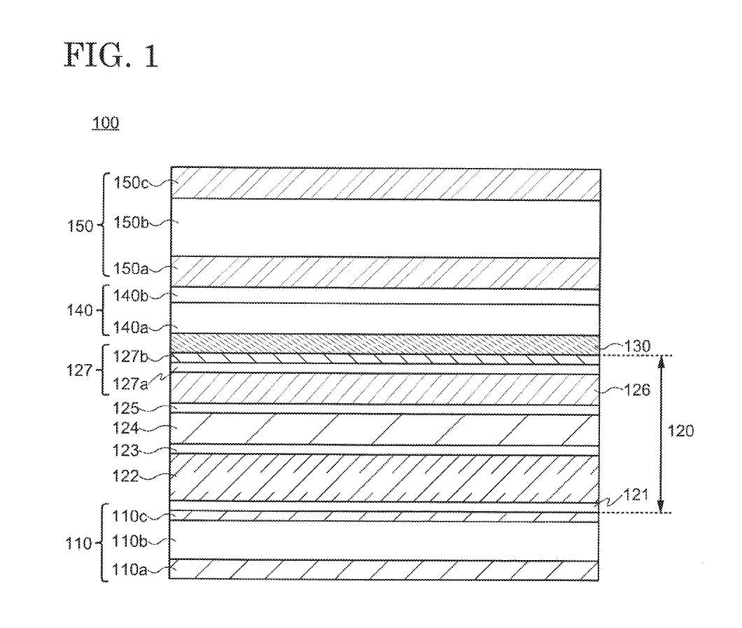

A structure of a light-emitting element 100 according to an embodiment of the present invention is explained by using FIG. 1 to FIG. 3.

### 1. Structure

A schematic cross-sectional view of the light-emitting element 100 is shown in FIG. 1. The light-emitting element 100 is structured by an anode 110, a cathode 130 over the anode 110, and an EL layer 120 positioned between the anode 110 and the cathode 130. The EL layer 120 possesses an emission layer 124, an electron-transporting layer 126, and an electron-injection layer 127. The electron-injection layer 127 has a structure in which two layers (a first electron-injection layer 127a and a second electron-injection layer 127b) are stacked. The first electron-injection layer 127a is in contact with the electron-transporting layer 126, while the second electron-injection layer 127b is in contact with the first electron-injection layer 127a and the cathode 130. The EL layer 120 may further include a hole-injection layer 121 over the anode 110, a hole-transporting layer 122 over the hole-injection layer 121, an electron-blocking layer 123 over the hole-transporting layer 122, and a hole-blocking layer 125 over the emission layer 124, and the like. Note that a substrate for supporting the light-emitting element 100 and a variety of circuits for driving the light-emitting element 100 are omitted in this cross-sectional view.

### 1-1. Anode

The anode 110 is an electrode provided to inject holes to the EL layer 120, and it is preferred that a surface thereof have a relatively high work function. As a specific material, a conductive oxide capable of transmitting visible light, such as indium-tin oxide (ITO) and indium-zinc oxide (IZO) is represented, and the material may further include silicon. The light-emitting element 100 demonstrated in FIG. 1 has a structure in which light emission obtained from the emission layer 124 is extracted through the cathode 130. Therefore, the anode 110 may further include a film containing a metal with high reflectance with respect to visible light, such as silver and aluminum. For example, the anode 110 may have a stacked-layer structure of a first conductive film 110a containing a conductive oxide, a second conductive film 110b containing a metal such as silver and aluminum, and a third conductive film 110c containing a conductive oxide as shown in FIG. 1.

### 1-2. Hole-Injection Layer

It is possible to use a compound to which holes are readily injected, that is, a compound readily oxidized (an electron-donating compound) in the hole-injection layer 121. In other words, a compound with a shallow HOMO level can be used. For example, an aromatic amine such as a benzidine derivative and a triarylamine, a carbazole derivative, a thiophene derivative, and a phthalocyanine derivative such as copper phthalocyanine, and the like can be used. Alternatively, a polythiophene derivative or a polyaniline derivative can be used, and poly(2,3-ethylenedioxythiophene)/poly(styrenesulfonic acid) is represented as an example. Alternatively, a mixture of an electron-donating compound such as the aforementioned aromatic amine and carbazole derivative as well as an aromatic hydrocarbon with an electron acceptor. As an electron acceptor, a transition-metal oxide such as vanadium oxide and molybdenum oxide, a nitrogen-containing heteroaromatic compound, a heteroaromatic compound having a strong electron-withdrawing group such as a cyano group, and the like are represented. These materials and the mixtures exhibit a small hole-injection barrier from the anode 110 because they have a low ionization potential. Thus, these materials and the mixture contribute to reduction of the driving voltage of the light-emitting element 100.

### 1-3. Hole-Transporting Layer

The hole-transporting layer 122 has a function to transport holes injected to the hole-injection layer 121 to a side of the emission layer 124, and materials the same as or similar to the materials usable in the hole-injection layer 121 can be used. For example, it is possible to use a material having a HOMO level deeper than that of the hole-injection layer 121 by approximately equal to or less than 0.5 eV or equal to or less than 0.3 eV. Since the materials described above have a hole-transporting property higher than an electron-transporting property, the holes are efficiently transported to a side of the emission layer 124, by which a low driving voltage of the light-emitting element 100 can be realized.

### 1-4. Electron-Blocking Layer

The electron-blocking layer 123 has a function to inhibit electrons injected form the cathode 130 from passing through the emission layer 124 and being injected to the hole-transporting layer 122 without contributing to recombination so that the electrons are confined in the emission layer 122 and energy transfer from an excited state obtained in the emission layer 124 to the molecules in the hole-transporting layer 122 is prevented. Therefore, a material is preferred which has a hole-transporting property larger than or similar to an electron-transporting property, which has a LUMO level shallower than that of the molecules in the emission layer 124, and which has a large band gap. Specifically, it is preferred that a difference in LUMO level between the molecules included in the electron-blocking layer 123 and the molecules included in the emission layer 124 be equal to or more than 0.2 eV, equal to or more than 0.3 eV, or equal to or more than 0.5 eV. In addition, a difference in band gap between the molecules included in the electron-blocking layer 123 and the molecules included in the emission layer 124 is preferred to be equal to or more than 0.2 eV, equal to or more than 0.3 eV, or equal to or more than 0.5 eV. In the case where an emission material is a phosphorescent material, it is preferred to use a material having a triplet level higher than that of the emission material by equal to or more than 0.2 eV, equal to or more than 0.3 eV, or equal to or more than 0.5 eV. More specifically, a carbazole derivative, an arylamine derivative, a thiophene derivative, or the like having a relatively small conjugation system is represented.

### 1-5. Emission Layer

The emission layer 124 is a layer supplying a space for recombination of the holes and electrons, and the light emission is obtained from this layer. The emission layer 124 may be composed of a single compound or have a so-called host-guest type structure. In the case of the host-guest type, a stillbene derivative, a condensed aromatic compound such as an anthracene derivative, a carbazole derivative, a metal complex including a quinolinol ligand, an aromatic amine, and a nitrogen-containing heteroaromatic compound such as a phenanthroline derivative, and the like can be used, for example. The guest functions as an emission material in the emission layer 124 of the host-guest type, and a fluorescent material such as a coumarin derivative, a pyran derivative, a quinacridone derivative, a tetracene derivative, a pyrene derivative, and an anthracene derivative or a phosphorescent material such as an iridium-based orthometal complex can be used. When the emission layer 124 is composed of a single compound, the host material described above can be used. In this case, the host material serves as an emission material.

### 1-6. Hole-Blocking Layer

The hole-blocking layer 125 has a function to inhibit holes injected form the anode 110 from passing through the emission layer 124 and being injected to the electron-transporting layer 126 without contributing to recombination so that the holes are confined in the emission layer 124 and energy transfer from an excited state obtained in the emission layer 124 to the molecules in the electron-transporting layer 126 is prevented. Moreover, as described below, since the electron-transporting layer 126 has a relatively high density of carrier electrons, and a quenching phenomenon readily occurs when an emission position in the emission layer 124 is close to the electron-transporting layer 126. In this case, formation of the hole-blocking layer 125 prevents the quenching phenomenon, by which a decrease in emission efficiency can be prevented.

It is preferred to use, for the hole-blocking layer 125, a material which has an electron-transporting property higher than or similar to a hole-transporting property, which has a HOMO level deeper than that of the molecules in the emission layer 124, and which has a large band gap. Specifically, it is preferred that a difference in HOMO level between the molecules included in the hole-blocking layer 125 and the molecules included in the emission layer 124 be equal to or more than 0.2 eV, equal to or more than 0.3 eV, or equal to or more than 0.5 eV. Furthermore, it is preferred that a difference in band gap between the molecules included in the hole-blocking layer 125 and the molecules included in the emission layer 124 be equal to or more than 0.2 eV, equal to or more than 0.3 eV, or equal to or more than 0.5 eV. When the emission material is a phosphorescent material, it is preferred to use a material having a triplet level higher than that of the emission material by equal to or more than 0.2 eV, equal to or more than 0.3 eV, or equal to or more than 0.5 eV. More specifically, a phenanthroline derivative, an oxadiazole derivative, a triazole derivative, a metal complex with a relatively large band gap (e.g., equal to or more than 2.8 eV) such as bis(2-methyl-8-qunolinolato)(4-hydroxybiphenyl)aluminum, and the like are represented.

### 1-7. Electron-Transporting Layer

The electron-transporting layer 126 has function to transport the electrons injected from the cathode 130 to the electron-injection layer 127 to a side of the emission layer 124. Here, the electron-transporting layer 126 is a mixed layer including two materials. One of the materials is an organic compound (first organic compound) having an electron-transporting property, and the other is a material exhibiting an electron-donating property with respect to the first organic compound.

A compound having an electron-transporting property is a compound having an electron-transporting property higher than a hole-transporting property and is selected from a substituted or unsubstituted aluminum complex, a substituted or unsubstituted beryllium complex, a substituted or unsubstituted zinc complex, a substituted or unsubstituted oxadiazole derivative, a substituted or unsubstituted triazole derivative, a substituted or unsubstituted silacyclopentadiene derivative, a substituted or unsubstituted anthracene derivative, a substituted or unsubstituted pyrene derivative, a substituted or unsubstituted perylene derivative, a substituted or unsubstituted phenanthroline derivative, and the like. As the metal complex described above, a metal complex having an 8-qunolinole ligand, such as tris(8-quinolinolato)aluminum (Alq) and bis(8-quinolinolato)beryllium, is exemplified. Here, a substituted or unsubstituted aluminum complex, a substituted or unsubstituted beryllium complex, and a substituted or unsubstituted zinc complex mean a complex having a ligand to which a substituent is introduced or a complex having an unsubstituted ligand. As a substituent, an alkyl group having 1 to 4 carbon atoms and an aryl group such as a phenyl group and a naphthyl group are represented.

An electron donor is a lithium metal (0 valent lithium), a lanthanide metal (0 valent lanthanide), or a metal complex having an 8-quinolinol ligand. As a lanthanide metal, ytterbium is represented. The metal complex has lithium or magnesium as a central metal, and a substituent may be introduced on the ligand. For example, (8-quinolinolato)lithium (hereinafter, referred to as Liq) and bis(8-quinolinolato)magnesium (hereinafter, referred to as Mgq) are represented as the metal complex.

In the electron-transporting layer 126 having such a structure, lithium (including lithium dissociated from Liq), Mg dissociated from Mgq, and ytterbium have a high electron-donating property, and charge transfer to the first organic compound occurs to form a charge-transfer complex. Hence, the anion radicals of the first organic compounds exist in the electron-transporting layer 126, increasing the electron density as a carrier. Accordingly, the electron-transporting layer 126 has a high electron-transporting property and is able to efficiently transport electrons injected from the second electron-injection layer 127b to the emission layer 124, which contributes to a decrease of the driving voltage of the light-emitting element 100.

### 1-8. Electron-Injection Layer

The electron-injection layer 127 has a function to promote electron injection from the cathode 130 to the EL layer 120. In the present embodiment, the electron-injection layer 127 has the first electron-injection layer 127a and the second electron-injection layer 127b in contact with each other.

The first electron-injection layer 127a includes a lithium metal or a lithium complex having an 8-quinolinol ligand, such as Liq. Alternatively, the first electron-injection layer 127a is composed of one of a lithium metal and a lithium complex having an 8-quinolinol ligand.

The second electron-injection layer 127b includes a lanthanide metal or is composed of a lanthanide metal. As a lanthanide metal, ytterbium is represented.

### 1-9. Cathode

The cathode 130 functions as a light-extracting electrode which injects electrons to the EL layer 120 and transmits the light emitted from the emission layer 124. Simultaneously, the cathode 130 is configured to partly reflect the light from the emission layer 124. Therefore, a microcavity is formed between the cathode 130 and the second conductive film 110b, and the light obtained in the emission layer 124 interferers and is amplified between the cathode 130 and the second conductive film 110b. As a result, a color purity of the emission color can be improved, and the luminance of the light-emitting element 100 in the front direction can be increased.

It is preferred to use a metal with a relatively low work function and a high conductivity for the cathode 130. Specifically, silver, magnesium, or an alloy thereof is used. As described above, the cathode 130 is configured to partly reflect and partly transmit the light emitted from the emission layer 124. Hence, a thickness of the cathode 130 is 5 nm to 30 nm or 10 nm to 20 nm, and typically 15 nm.

A thickness of each functional layer described above may be appropriately determined. For example, a thickness of the hole-injection layer 121 is equal to or larger than 5 nm and equal to or smaller than 50 nm, equal to or larger than 10 nm and equal to or smaller than 30 nm, or equal to or larger than 10 nm and equal to or smaller than 20 nm, and typically 10 nm. A thickness of the hole-transporting layer 122 is equal to or larger than 50 nm and equal to or smaller than 300 nm, equal to or larger than 100 nm and equal to or smaller than 200 nm, or equal to or larger than 110 nm and equal to or smaller than 150 nm. The thicknesses of the hole-injection layer 121 and the hole-transporting layer 122 may be appropriately adjusted in accordance with an emission wavelength of the emission material. Specifically, the thicknesses may be adjusted so that an optical distance from the emission position in the emission layer 124 to a surface of the second conductive film 110b is equal to or close to an integral multiple of half of the emission peak wavelength (half wavelength) of the emission material. This configuration allows the light emitted from the emission layer 124 and the light reflected at the surface of the second conductive film 110b to amplify each other, by which the emission spectrum can be narrowed, and the emission intensity can be increased.

Thicknesses of the electron-blocking layer 123 and the hole-blocking layer 125 are each equal to or larger than 5 nm and equal to or smaller than 20 nm or equal to or larger than 5 nm and equal to or smaller than 15 nm, and typically 10 nm. A thickness of the emission layer 124 is equal to or larger than 5 nm and equal to or smaller than 40 nm, equal to or larger than 10 nm and equal to or smaller than 35 nm, or equal to or larger than 10 nm and equal to or smaller than 30 nm, and typically 15 nm. A thickness of the electron-transporting layer 126 is equal to or larger than 5 nm and equal to or smaller than 40 nm, equal to or larger than 10 nm and equal to or smaller than 30 nm, or equal to or larger than 15 nm and equal to or smaller than 30 nm, and typically 25 nm. Thicknesses of the first electron-injection layer 127a and the second electron-injection layer 127b are each equal to or larger than 0.5 nm and equal to or smaller than 5 nm or equal to or larger than 1 nm and equal to or smaller than 3 nm, and typically 1 nm.

As described above, the light-emitting element 100 is a so-called top-emission type light-emitting element in which the emitted light is extracted from the cathode 130. In this case, it is preferred to control the thickness of each layer so that a total thickness of the hole-blocking layer 125, the electron-transporting layer 126, the first electron-injection layer 127a, and the second electron-injection layer 127b is 25 nm to 30 nm. With this configuration, the interference effect and amplification effect of the light emission can be more efficiently obtained, thereby improving emission efficiency and color purity.

The anode 110 is prepared with a chemical vapor deposition (CVD) method, an evaporation method, or a sputtering method. Each functional layer and the cathode 130 are prepared with an ink-jet method, a spin-coating method, a printing method, or an evaporation method. The cathode 130 may be formed with a sputtering method.

As described above, in the light-emitting element 100 with such a structure, the electron-transporting layer 126 has a high electron mobility due to the high electron-carrier concentration thereof. Hence, the electrons injected to the second electron-injection layer 127b are readily transported to the emission layer 124. Accordingly, implementation of the present embodiment enables production of a light-emitting element with a low driving voltage and reduced power consumption.

When the cathode 130 is prepared over the second electron-injection layer 127b with an evaporation method, vapor of magnesium or silver vaporized in an evaporation source collides with the second electron-injection layer 127b and then is cooled to be deposited, resulting in the first electron-injection layer 127a. The collision energy at that time causes a reaction of a part of the metal in the cathode 130 with the lanthanide metal to form an alloy, which leads to a decrease in an electron-injection barrier from the cathode 130 to the second electron-injection layer 127b. Similarly, when the first electron-injection layer 127a is formed, the material vaporized in an evaporation source collides with the electron-transporting layer 126 and is cooled to be deposited, resulting in the first electron-injection layer 127a. At this time, the lithium metal included in the first electron-injection layer 127a partly enters into the electron-transporting layer 126 by the collision energy. Similarly, in the case where the first electron-injection layer 127a is formed by using Liq, a part of Liq included in the first electron-injection layer 127a is decomposed by the collision energy, which allows a part of the lithium resulting from the collision to enter the inside of the electron-transporting layer 126. Accordingly, the electron density of the electron-transporting layer 126 is further increased, and the electron-transporting property of the electron-transporting layer 126 is improved. Hence, the driving voltage of the light-emitting element 100 can be further reduced.

### 1-10. Other Structures

As shown in FIG. 1, the light-emitting element 100 may further possess, as an optional structure, a cap layer 140 and a sealing layer (hereinafter, referred to as a passivation film) 150.

In the case where the cap layer 140 is disposed, the cap layer 140 is formed so as to be in contact with the cathode 130. The cap layer 140 may have a single-layer structure or a two-layer structure of a first cap layer 140a and a second cap layer 140b as shown in FIG. 1. The formation of the cap layer 140 allows an additional formation of a microcavity over the cathode 130. Therefore, the light passing through the cathode 130 is further amplified by the interference effect through repeated reflection between a bottom surface (i.e., an interface between the cap layer 140 and the cathode 130) of the cap layer 140 and a top surface thereof.

The first cap layer 140a may include a material having a high transmittance and a relatively high refraction index in the visible region. As an example of such a material, an organic compound is represented. As an organic compound, a polymer material is representative, and a polymer material including sulfur, halogen, or phosphorous is exemplified. As a polymer including sulfur, a polymer having a substituent such as a thioether, a sulfone, and a thiophene in the main or side chain is given. As a polymer material including phosphorous, a polymer material including a phosphorous acid, a phosphoric acid, or the like in the main or side chain, a polyphosphazene, or the like is represented. As a polymer material including halogen, a polymer material including bromine, iodine, or chlorine as a substituent is exemplified. Alternatively, the first cap layer 140a may include an inorganic compound, and titanium oxide, zirconium oxide, chromium oxide, aluminum oxide, indium oxide, ITO, IZO, lead sulfide, zinc sulfide, silicon nitride, and the like are exemplified as an inorganic compound. A mixture of the inorganic compound and the polymer material may be used.

The second cap layer 140b may include a material having a high transmittance and a relatively low refractive index in the visible region. As an example, a polymer including fluorine is represented. As a polymer material including fluorine, polytetrafluoroethylene, poly(vinylidene fluoride), and a derivative thereof as well as a poly(vinyl ether), a polyimide, a poly(methacrylic ester), a poly(acrylic ester), and a polysiloxane which include fluorine in the main chain or side chain, and the like are represented.

The refractive indexes of the materials and the thicknesses of the first cap layer 140a and the second cap layer 140b are adjusted as appropriate so that an optical distance of the cap layer 140 is the same as or close to an odd multiple of one fourth of an emission peak wavelength of the emission layer 124. This structure reduces the full-width half-maximum of the obtained emission and enables improvement of color purity and a luminance of the light-emitting element 100 in a front direction.

The passivation film 150 has a function to prevent the entrance of impurities such as water and oxygen from the outside to the light-emitting element 100, thereby improving reliability of the light-emitting element 100. The passivation film 150 is formed so as to be in contact with the cap layer 140. When the cap layer 140 is not provided, the passivation film 150 is disposed so as to be in contact with the cathode 130.

The structure of the passivation film 150 is arbitrarily determined, and the passivation film 150 may have a three-layer structure shown in FIG. 1. In this case, the passivation film 150 may possess a first layer 150a, a second layer 150b, and a third layer 150c. For example, the first layer 150a and the third layer 150c can be formed with an inorganic compound including silicon nitride, silicon oxide, or the like, and the second layer 150b can be formed with an organic compound including an acrylic resin.

### 2. Modified Example

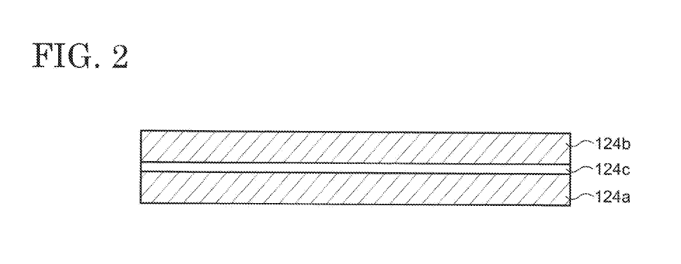

The structure of the light-emitting element 100 according to the present embodiment is not limited to that described above. For example, although the emission layer 124 has a single layer in the example demonstrated in FIG. 1, the emission layer 124 may be composed of a plurality of emission layers. Specifically, the emission layer 124 may have a structure in which a first emission layer 124a and a second emission layer 124b are stacked as shown in FIG. 2. The first emission layer 124a and the second emission layer 124b may include the same emission material, or the emission materials may be selected to give emission colors different from each other.

The first emission layer 124a and the second emission layer 124b may be in contact with each other or may be stacked via a charge-generation layer 124c. As the charge-generation layer 124c, a stacked structure of a mixed layer of the aforementioned compound exhibiting an electron-transporting property and the electron donor and a mixed layer of the electron-donating compound and the electron acceptor may be employed. The use of such a structure allows production of the light-emitting element 100 having an almost doubled current efficiency.

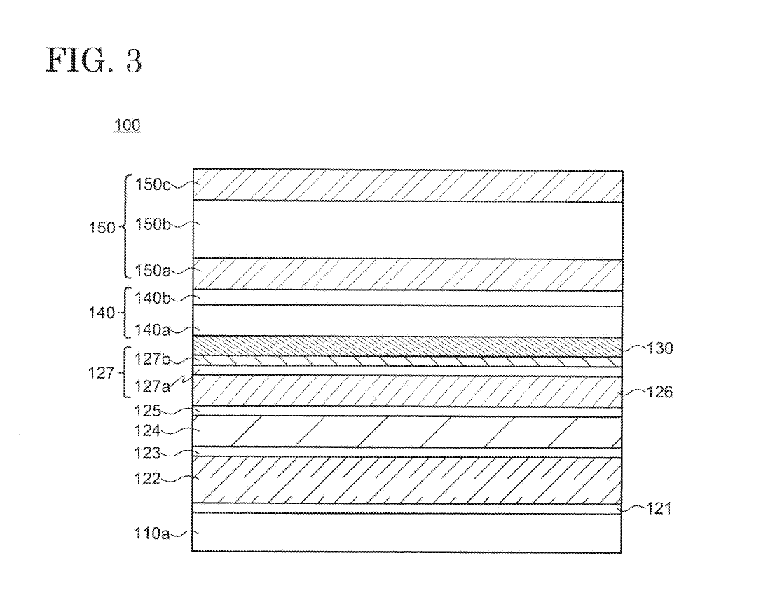

The light-emitting element 100 may be configured so that the light is extracted from the anode 100. In this case, the second conductive film 110b which efficiently reflects visible light is not formed in the anode 110, but the first conductive film 110a (or the third conductive film 110c) including ITO or IZO is employed as shown in FIG. 3. On the other hand, the cathode 130 is formed at a thickness which allows visible light to be efficiently reflected. For example, the light-emitting element 100 may be configured so that the thickness of the cathode 130 is equal to or larger than 30 nm and equal to or smaller than 300 nm, equal to or larger than 50 nm and equal to or smaller than 200 nm, or equal to or larger than 100 nm and equal to or smaller than 200 nm.

### Second Embodiment

In the present embodiment, a structure of a display device 200 arranged with a plurality of pixels 204 having the light-emitting element 100 is described. An explanation of the structures the same as or similar to those of the First Embodiment may be omitted.

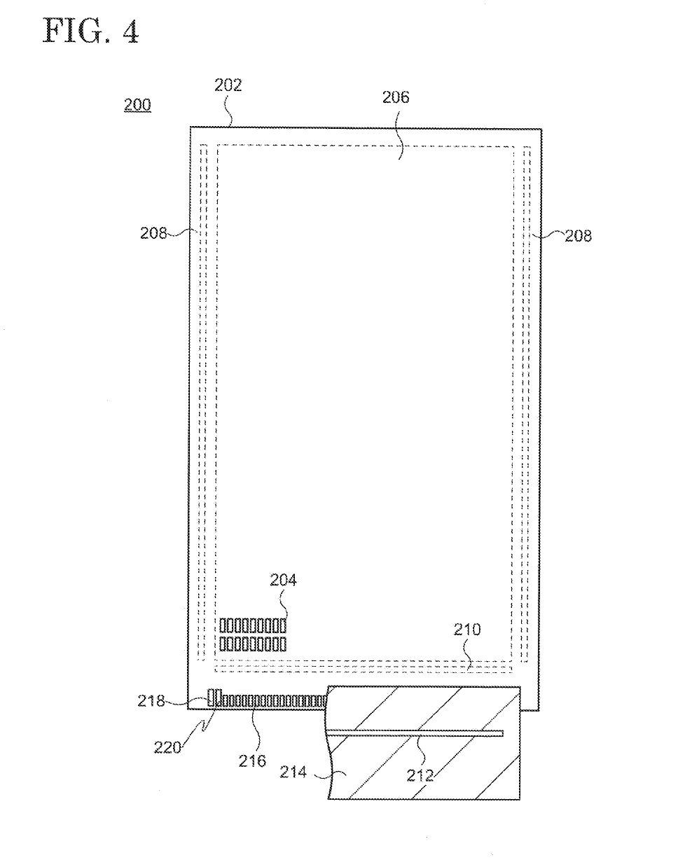

A schematic top view of the display device 200 is shown in FIG. 4. The display device 200 possesses a substrate 202 and a variety of patterned insulating films, semiconductor films, and conductive films thereover. A plurality of pixels 204 and driver circuits (gate-side driver circuits 208 and source-side driver circuit 210) for driving the pixels 204 are formed by these insulating films, semiconductor films, and conductive films. The plurality of pixels 204 is periodically arranged and defines a display region 206. As described below, the light-emitting element 100 is disposed in each pixel 204.

The gate-side driver circuits 208 and the source-side driver circuit 210 are arranged outside the display region 206 (peripheral region). A variety of wirings 292 (not illustrated in FIG. 4) formed with the patterned conductive films extends from the display region 206, the gate-side driver circuits 208, and the source-side driver circuit 210 to a side of the substrate 202 and is exposed at a vicinity of an edge portion of the substrate 202 to form terminals such as image-signal terminals 216 and power-source terminals 218 and 220. These terminals are electrically connected to a flexible printed circuit substrate (FPC) 214. In the example shown here, a driver IC 212 having an integrated circuit formed over a semiconductor substrate is mounted over the FPC 214. Image signals are supplied from an external circuit (not illustrated) through the driver IC 212 and FPC 214 and transmitted to the gate-side driver circuits 208 and the source-side driver circuit 210 through the image-signal terminals 216. A power source supplied to the light-emitting elements 100 in the pixels 204 is provided to the display device 200 through the FPC 214 and the power-source terminals 218 and 220. A high potential (PVDD) is provided to the power-source terminals 220, while a potential PVSS lower than PVDD is provided to the power-source terminals 218. Signals based on these image signals and potentials are supplied to each pixel 204, by which the pixels 204 are controlled and operated. The configuration of the driver circuits and the driving IC 212 is not limited to that of FIG. 4. For example, the driver IC 112 may be mounted over the substrate 202, and the function of the source-side driver circuit 210 may be integrated with the driver IC 212.

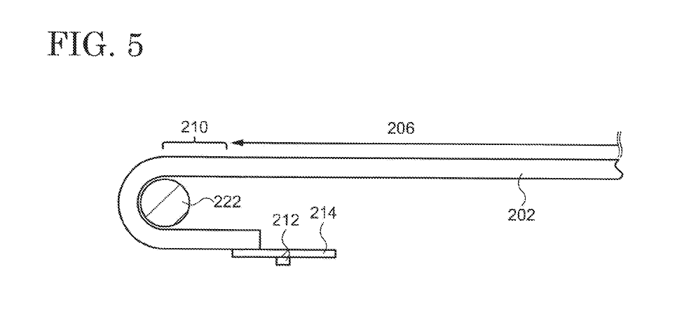

Use of a flexible substrate as the substrate 202 provides the display device 200 with flexibility. For example, the display device 200 can be folded between the terminals and the display region 206 so that the FPC 214 and the terminals connected thereto overlap with the display region 206 as shown in a side view of FIG. 5. At this time, a spacer 222 may be disposed to stabilize the folded structure. At least a part of an outer circumference of the spacer 222 is covered by the substrate 202.

### 2. Structure of Pixel

### 2-1. Pixel Circuit

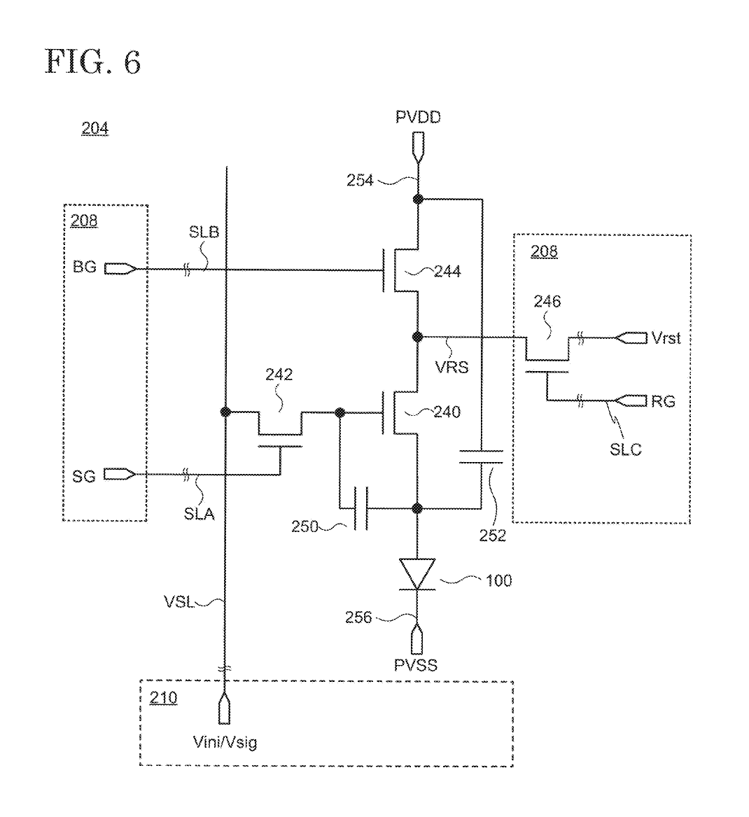

A pixel circuit including the light-emitting element 100 is structured with a variety of patterned insulating films, semiconductor films, and conductive films in each pixel 204. The structure of the pixel circuit can be arbitrarily selected, and an example is demonstrated as an equivalent circuit in FIG. 6.

The pixel circuit shown in FIG. 6 includes a driving transistor 240, a first switching transistor 242, a second switching transistor 244, a storage capacitor 250, and a supplementary capacitor 252 in addition to the light-emitting element 100. The light-emitting element 100, the driving transistor 240, and the second switching transistor 244 are connected in series between a high-potential power-source line 254 and a low-potential power-source line 256. PVDD and PVSS are respectively supplied to the high-potential power-source line 254 and the low-potential power-source line 256.

In the present embodiment, the driving transistor 240 is assumed to be an n-channel type, and input-output terminals on a side of the high-potential power-source line 254 and a side of the light-emitting element 100 are defined as a drain and a source, respectively. The drain of the driving transistor 240 is electrically connected to the high-potential power-source line 254 through the second switching transistor 244, and the source thereof is electrically connected to the anode 110 of the light-emitting element 100.

A gate of the driving transistor 240 is electrically connected to a first signal line VSL through the first switching transistor 242. Operation (on/off) of the first switching transistor 242 is controlled with a scanning signal SG supplied to a first scanning signal line SLA connected to a gate thereof. When the first switching transistor 242 is on, a potential of the first signal line VSL is provided to the gate of the driving transistor 240. An initialization signal Vini and an image signal Vsig are provided to the first signal line VSL at a predetermined timing. The initialization signal Vini is a signal giving an initialization potential with a constant level. The on/off of the first switching transistor 242 is controlled at a predetermining timing while synchronizing with the first signal line VSL, and a potential based on the initialization signal Vini or the image signal Vsig is provided to the gate of the driving transistor 240.

A second signal line VRS is electrically connected to the drain of the driving transistor 240. A reset potential Vrst is supplied to the second signal line VRS through a reset transistor 246. A timing at which the reset signal Vrst is applied through the reset transistor 246 is controlled by a reset signal RG provided to a third signal line SLC.

The storage capacitor 250 is disposed between the source and drain of the driving transistor 240. One terminal of the supplementary capacitor 252 is connected to the source of the driving transistor 240, and the other terminal is connected to the high-potential power-source line 254. The supplementary capacitor 252 may be formed so that the other terminal is connected to the low-potential power-source line 256. The storage capacitor 250 and the supplementary capacitor 252 are provided to maintain a source-drain voltage Vgs corresponding to the image signal Vsig when the image signal Vsig is provided to the gate of the driving transistor 240.

The source-side driver circuit 210 outputs the initialization signal Vini or the image signal Vsig to the first signal line VSL. The gate-side driver circuits 208 output the scanning signal SG, a scanning signal BG, and the reset signal RG to the first scanning line SLA, a second scanning line SLB, and the third signal line SLC, respectively.

### 2-2. Cross-Sectional Structure

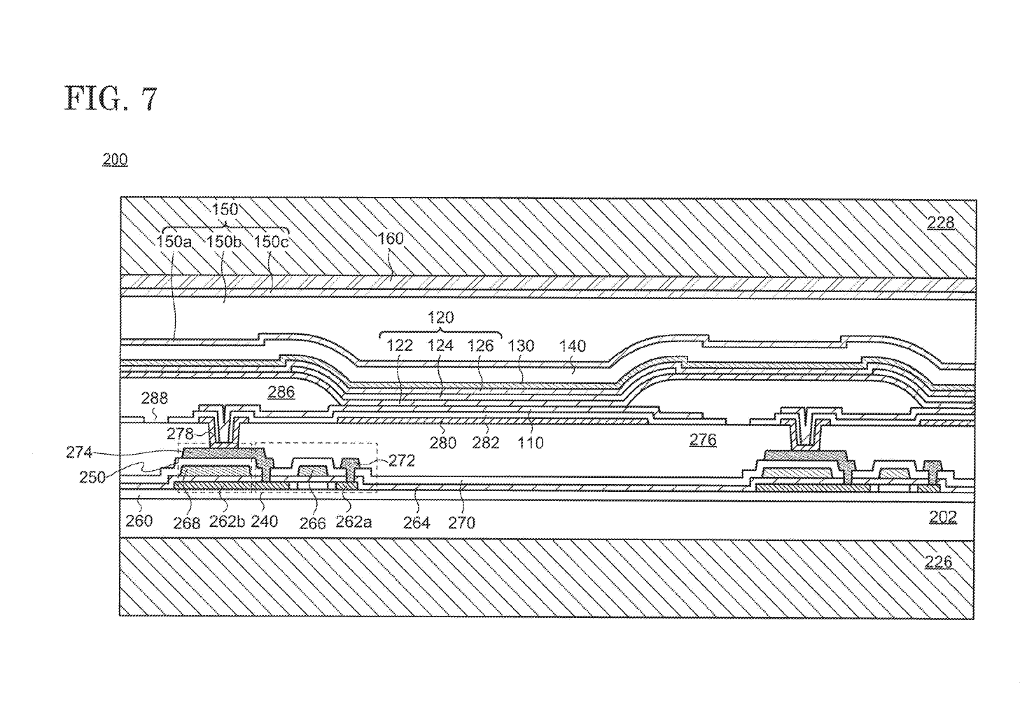

A structure of the pixel 204 is explained by using a cross-sectional structure in FIG. 7. In FIG. 7, the cross-sectional structures of the driving transistor 240, the storage capacitor 250, the supplementary capacitor 252, and the light-emitting element 100 of the pixel circuits of adjacent two pixels 204 formed over the substrate 202 are illustrated.

Each element included in the pixel circuit is disposed over the substrate 202 through an undercoat 260. The driving transistor 240 includes a semiconductor film 262, a gate insulating film 264, a gate electrode 266, a drain electrode 272, and a source electrode 274. The gate electrode 266 is arranged to intersect at least a part of the semiconductor film 262 via the gate insulating film 264, and a channel is formed in a region where the gate electrode 266 overlaps with the semiconductor film 262. The semiconductor film 262 further possesses a drain region 262a and a source region 262b sandwiching the channel.

A capacitor electrode 268 existing in the same layer as the gate electrode 266 is formed to overlap with the source region 262b through the gate insulating film 264. An interlayer insulating film 270 is disposed over the gate electrode 266 and the capacitor electrode 268. Openings reaching the drain region 262a and the source region 262b are formed in the interlayer insulating film 270 and the gate insulating film 264, and the drain electrode 272 and the source electrode 274 are arranged so as to cover the openings. A part of the source electrode 274 overlaps with a part of the source region 262b through the interlayer insulating film 270, and the storage capacitor 250 are structured by the part of the source region 262b, the gate insulating film 264, the capacitor electrode 268, the interlayer insulating film 270, and the part of the source electrode 274.

A leveling film 276 is further provided over the driving transistor 240 and the storage capacitor 250. The leveling film 276 has an opening reaching the source electrode 274, and a connection electrode 278 covering this opening and a part of a top surface of the leveling film 276 is formed to be in contact with the source electrode 274. The supplementary capacitor electrode 280 is further disposed over the leveling film 276. The connection electrode 278 and the supplementary capacitor electrode 280 may be simultaneously formed and can exist in the same layer. A capacitor insulating film 282 is formed to cover the connection electrode 278 and the supplementary capacitor electrode 280. The capacitor insulating film 282 does not cover a part of the connection electrode 278 in the opening of the leveling film 176 to expose a top surface of the connection electrode 278. This structure enables an electrical connection between the anode 110 formed over the connection electrode 278 and the source electrode 274 via the connection electrode 278. An opening 288 may be formed in the capacitor insulating film 282 to allow contact of a partition wall 286 formed thereover with the leveling film 276. Impurities in the leveling film 276 can be removed through the opening 288, thereby improving reliability of the light-emitting element 100. Note that the formation of the connection electrode 278 and the opening 288 is optional.

The anode 110 is disposed over the capacitor insulating film 282 to cover the connection electrode 278 and the supplementary capacitor electrode 280. The capacitor insulating film 282 is sandwiched by the supplementary capacitor electrode 280 and the anode 110, and the supplementary capacitor 252 is configured by this structure. The anode 110 is shared by the supplementary capacitor 252 and the light-emitting element 100.

The partition wall 286 is provided over the anode 110 to cover an edge portion of the anode 110. The EL layer 120 and the cathode 130 thereover are arranged so as to cover the partition wall 286. The structures of the anode 110, the cathode 130, and the EL layer 120 are the same as those described in the First Embodiment. The structure of the EL layer 120 may be the same in all of the pixels 204, or the EL layer 120 may be formed so that a part of the structure is different between adjacent pixels 204. For example, the pixels 204 may be configured so that the structure or material of the emission layer 124 is different but other layers have the same structure between adjacent pixels 204. Furthermore, the pixels 204 may be configured so that the thickness of the hole-transporting layer 122 in addition to the structure and material of the emission layer 124 are different but other layers have the same structure between adjacent pixels 204. The cathode 130 covers the plurality of pixels 204. That is, the cathode 130 is shared by the plurality of pixels 204. Note that the hole-transporting layer 122, the emission layer 124, and the electron-transporting layer 126 are demonstrated as the representative functional layers in FIG. 7 for visibility.

The cap layer 140 is disposed over the cathode 130. The cap layer 140 also covers the plurality of pixels 204 so as to be shared by the plurality of pixels 204. In the case where the cap layer 140 is provided with the interference and amplification effects of the light from the emission layer 124 as described above, the cap layer 140 may be configured so that the thickness thereof is different between adjacent pixels 204. The passivation film 150 for protecting the light-emitting elements 100 is arranged over the cap layer 140. A film (hereinafter, referred to as a resin film) 160 including a resin is disposed over the passivation film 150. The display device 200 further possesses supporting films 226 and 228 sandwiching the structure from the substrate 202 to the resin film 160, and appropriate physical strength is provided by the supporting films 226 and 228.

The supporting films 226 and 228 are respectively fixed to the substrate 202 and the resin film 160 with an adhesive layer which is not illustrated.

### 3. Terminals and Wirings

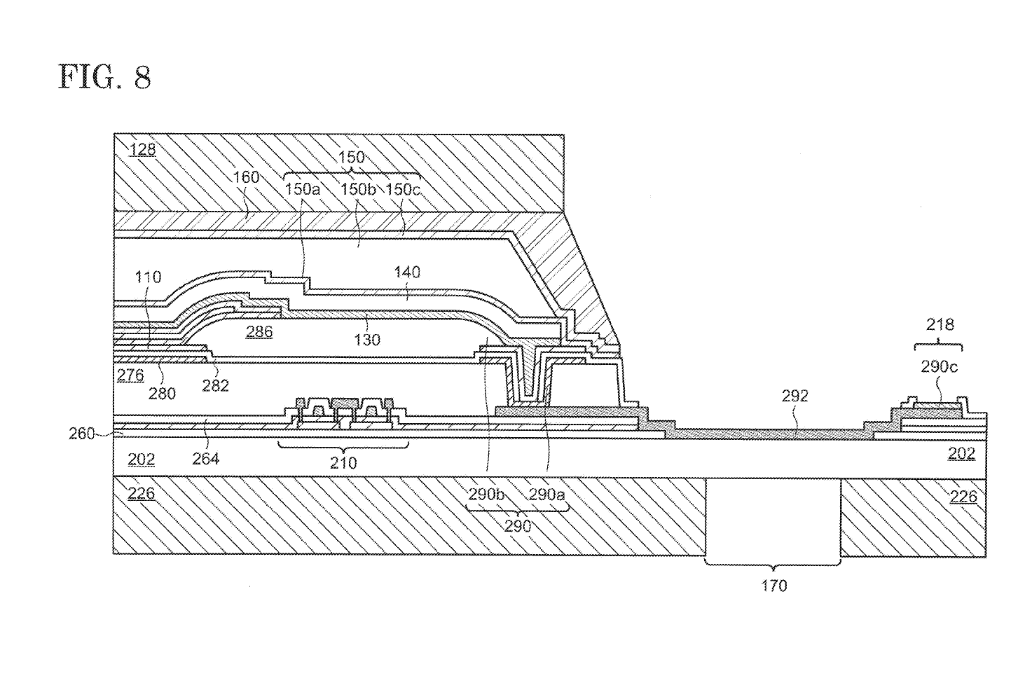

FIG. 8 schematically shows an example of a cross-sectional structure focusing on the region from an edge portion of the display region 206 (lower portion of the display region 206 in FIG. 4) to the power-source terminals 218 and 220 and the image-signal terminals 216. Here, the cross-sections of a part of the display region 206, the source-side driver circuit 210, the power-source terminal 218, and the wiring 292 electrically connecting the display region 206 to the power-source terminal 218 are illustrated.

As shown in FIG. 8, the supporting film 226 is divided into two portions by removing a part thereof, and an undersurface of the substrate 202 is exposed between the divided portions. The portion where the supporting film 226 is removed has high flexibility, and the three-dimensional structure demonstrated in FIG. 5 can be provided to the display device 200 by utilizing this portion to fold the substrate 202. Hereinafter, the portion where the supporting film 226 is removed is called a bent region 170.

The undercoat 260 extends to the power-source terminal 218 from the pixel 204, and a part of the undercoat 260 is removed in the bent region 170 and at a vicinity thereof. That is, the undercoat 260 is divided in the bent region 170. Similar to the undercoat 260, the gate insulating film 264 and the interlayer insulating film 270 formed in the display region 206 also extend in a direction toward the power-source terminal 218 and are each divided in the bent region 170. Semiconductor elements such as a transistor are provided in the source-side driver circuit 210, and a variety of circuits such as an analogue circuit are structured by the semiconductor elements.

The wiring 292 extends to the edge portion of the substrate 202 from the display region 206. The cathode 130 provided in the display region 206 is electrically connected to the wiring 292 in an opening formed in the leveling film 276. Specifically, the leveling film 276 has the opening reaching the wiring 292 between the display region 260 and the power-source terminal 218, and a contact electrode 290 including a first contact electrode 290a and a second contact electrode 290b over the first contact electrode 290a is arranged so as to cover this opening. The cathode 130 is electrically connected to the wiring 292 through the second contact electrode 290b and the first contact electrode 290a.

The wiring 292 further forms the power-source terminals 218 and 220 and the image-signal terminals 216 at the vicinity of the edge portion of the substrate 202. Surfaces of these terminals may be covered with the protection electrodes 290c existing in the same layer as the first contact electrode 290a. As described above, these terminals are input with a variety of signals for driving the pixels 204.

As described in the First Embodiment, the light-emitting element 100 possesses: the electron-transporting layer 126 which is a mixed layer of an organic compound having an electron-transporting property and an electron donor selected from lithium, a lithium complex having a quinolinol ligand, and a magnesium complex having a quinolinol ligand; the first electron-injection layer 127a including lithium or a lithium complex having a quinolinol ligand, such as Liq; and the second electron-injection layer 127b including a lanthanide metal. Therefore, the light-emitting element 100 exhibits a low driving voltage and has reduced power consumption. Hence, introduction of the light-emitting element 100 to each pixel 204 enables the display device 200 to demonstrate low power consumption. That is, implementation of the present embodiment allows production of a display device having a low driving voltage and low power consumption.

### Example

In the present example, fabrication of the light-emitting element 100 described in the First Embodiment and evaluation of the performance thereof are demonstrated. Specifically, blue-emissive light-emitting elements 1 to 4 as the light-emitting element according to the embodiment of the present invention and a blue-emissive light-emitting element 5 as a comparative example were fabricated.

Each of the light-emitting elements 1 to 4 is one of the light-emitting elements 100 of the First Embodiment, and their structures are the same as one another except for the structures of the electron-transporting layer 126 and the first electron-injection layer 127a. The electron-transporting layers 126 and the electron-injection layers 127a of these elements are shown in FIG. 1. The light-emitting element 5 is different from the light-emitting elements 1 and 2 in that the first electron-injection layer 127a is not provided (see Table 1).

TABLE 1
Structures of the light-emitting elements 1 to 5

| | Electron-transporting layer | | | | |
|---|---|---|---|---|---|
| | Compound | | | | |
| | with | | | | |
| | electron- | | | First | Second |
| | trans- | | | electron- | electron- |
| | portiong | Electron | Volume | injection | injection |
| | property | donor | ratio | layer | layer |
| Light-emitting | Alq | Liq | 1:1 | Li | Yb |
| element 1 | | | | | |
| Light-emitting | Alq | Liq | 1:1 | Liq | Yb |
| element 2 | | | | | |
| Light-emitting | Alq | Liq | 9:1 | Liq | Yb |
| element 3 | | | | | |
| Light-emitting | Alq | Yb | 9:1 | Liq | Yb |
| element 4 | | | | | |
| Light-emitting | Alq | Liq | 1:1 | — | Yb |
| element 5 | | | | | |

The driving voltage, the emission efficiency, and the time for 5% luminance deterioration (Lt95) of each element are summarized in Table 2. Here, the driving voltage and the emission efficiency are values when current flows in the light-emitting element at a current density of 10 mA/cm². Lt95 is a time when the light-emitting element is driven at a constant current of 15 mA/cm² at 30° C. and the luminance becomes 95% of the initial luminance.

TABLE 2
Performance of light-emitting elements 1 to 5

| | Driving voltage | Emission efficiency | Lt95 |
|---|---|---|---|
| | (V) | (Cd/A) | (h) |
| Light-emitting | 4.4 | 4.6 | 400 |
| element 1 | | | |
| Light-emitting | 4.8 | 4.5 | 500 |
| element 2 | | | |
| Light-emitting | 4.5 | 4.4 | 550 |
| element 3 | | | |
| Light-emitting | 4.6 | 4.6 | 500 |
| element 4 | | | |
| Light-emitting | 5.2 | 3.7 | 300 |
| element 5 | | | |

As can be clearly understood from Table 2, all of the light-emitting elements 1 to 4 which are the light-emitting elements 100 according to an embodiment of the present invention can be driven at a low voltage and exhibits high emission efficiency and reliability. In contrast, it was confirmed that, with respect to the light-emitting element 5 without the first electron-injection layer 127a, the driving voltage is increased, and the emission efficiency is low. In addition, a decrease in reliability was observed. From these results, it was revealed that implementation of an embodiment of the present invention allows production of a light-emitting element which can be driven at a low voltage and shows low power consumption and a display device including the same.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process is included in the scope of the present invention as long as they possess the concept of the present invention.

It is properly understood that another effect different from that provided by the modes of the aforementioned embodiments is achieved by the present invention if the effect is obvious from the description in the specification or readily conceived by persons ordinarily skilled in the art.

What is claimed is:

1. A light-emitting element comprising:
an anode;
an emission layer over the anode;
an electron-transporting layer over the emission layer, the electron-transporting layer including:
a first organic compound having an electron-transporting property higher than a hole-transporting property; and
at least one of lithium, a lithium complex containing an 8-quinolinol ligand, and a magnesium complex containing an 8-quinolinol ligand;
a first electron-injection layer over and in contact with the electron-transporting layer, the first electron-injection layer including at least one of lithium and a lithium complex containing an 8-quinolinol ligand;
a second electron-injection layer over and in contact with the first electron-injection layer, the second electron-injection layer including a lanthanoid metal; and
a cathode over and in contact with the second electron-injection layer.

2. The display device according to claim 1,
wherein the lanthanoid metal is ytterbium.

3. The display device according to claim 1,
wherein the first organic compound includes one of a substituted or unsubstituted aluminum complex, a substituted or unsubstituted beryllium complex, a substituted or unsubstituted zinc complex, a substituted or unsubstituted oxadiazole derivative, a substituted or unsubstituted triazole derivative, a substituted or unsubstituted silacyclopentadiene derivative, a substituted or unsubstituted anthracene derivative, a substituted or unsubstituted pyrene derivative, a substituted or unsubstituted perylene derivative, and a substituted or unsubstituted phenanthroline derivative.

4. The display device according to claim 1,
wherein the lithium complex containing an 8-quinolinol ligand and the magnesium complex containing an 8-quinolinol ligand are (8-quinolinolato)lithium and bis(8-quinolinolato)magnesium, respectively.

5. The display device according to claim 1,
wherein the first electron-injection layer includes lithium or (8-quinolinolato)lithium.

6. The display device according to claim 1,
wherein the second electron-injection layer includes ytterbium.

7. The display device according to claim 1,
wherein the cathode includes magnesium and silver.

8. The display device according to claim 1,
wherein the cathode is configured to partly reflect and partly transmit visible light.

9. The display device according to claim 1, further comprising a hole-blocking layer between and in contact with the emission layer and the electron-transporting layer.

10. The display device according to claim 9,
wherein a total thickness of the hole-blocking layer, the electron-transporting layer, the first electron-injection layer, and the second electron-injection layer is equal to or larger than 25 nm and equal to or smaller than 35 nm.

11. A display device comprising a pixel having a light-emitting element, the light-emitting element including:
an anode;
an emission layer over the anode;
an electron-transporting layer over the emission layer, the electron-transporting layer including:
a first organic compound having an electron-transporting property higher than a hole-transporting property; and
at least one of lithium, a lithium complex containing an 8-quinolinol ligand, and a magnesium complex containing an 8-quinolinol ligand;
a first electron-injection layer over and in contact with the electron-transporting layer, the first electron-injection layer including at least one of lithium and a lithium complex containing an 8-quinolinol ligand;
a second electron-injection layer over and in contact with the first electron-injection layer, the second electron-injection layer containing a lanthanide metal; and
a cathode over and in contact with the second electron-injection layer.

12. The display device according to claim 11,
wherein the lanthanide metal is ytterbium.

13. The display device according to claim 11,
wherein the first organic compound includes a substituted or unsubstituted aluminum complex, a substituted or unsubstituted beryllium complex, a substituted or unsubstituted zinc complex, a substituted or unsubstituted oxadiazole derivative, a substituted or unsubstituted triazole derivative, a substituted or unsubstituted silacyclopentadiene derivative, a substituted or unsubstituted anthracene derivative, a substituted or unsubstituted pyrene derivative, a substituted or unsubstituted perylene derivative, and a substituted or unsubstituted phenanthroline derivative.

14. The display device according to claim 11,
wherein the lithium complex containing an 8-quinolinol ligand and the magnesium complex containing an 8-quinolinol ligand are (8-quinolinolato)lithium and bis(8-quinolinolato)magnesium, respectively.

15. The display device according to claim 11,
wherein the first electron-injection layer includes lithium or (8-quinolinolato)lithium.

16. The display device according to claim 11,
wherein the second electron-injection layer includes ytterbium.

17. The display device according to claim 11,
wherein the cathode includes magnesium and silver.

18. The display device according to claim 11,
wherein the cathode is configured to partly reflect and partly transmit visible light.

19. The display device according to claim 11, further comprising a hole-blocking layer between and in contact with the emission layer and the electron-transporting layer.

20. The display device according to claim 19,
wherein a total thickness of the hole-blocking layer, the electron-transporting layer, the first electron-injection layer, and the second electron-injection layer is equal to or larger than 25 nm and equal to or smaller than 35 nm.
